(19) United States
(12) Patent Application Publication
(10) Pub. No.: US 2024/0124981 A1
(43) Pub. Date: Apr. 18, 2024

(54) GAS INLET TUBE ASSEMBLY FOR AN IMPROVED GAS MIXTURE IN A SUBSTRATE PROCESSING APPARATUS

(71) Applicant: ASM IP Holding B.V., Almere (NL)

(72) Inventors: Arun Thottappayil, Hwaseong (KR); DongRak Jung, Hwaseong (KR); JongSu Kim, Hwaseong-si, Gyeonggi-do (KR)

(21) Appl. No.: 18/377,885

(22) Filed: Oct. 9, 2023

Related U.S. Application Data
(60) Provisional application No. 63/415,388, filed on Oct. 12, 2022.

(51) Int. Cl. C23C 16/455

(52) U.S. Cl. CPC C23C 16/45565

(57) ABSTRACT

A gas inlet tube assembly is presented. The assembly comprising a first inlet configured to insert a first process gas and a second inlet configured to insert a second process gas; a gas inlet tube configured to mix the first process gas from the first inlet and the second process gas from the second inlet, the gas inlet tube being in fluid communication with a reaction chamber of the substrate processing apparatus, comprising upper and lower segments, wherein the first inlet and the second inlet are placed in the upper segment of the gas inlet tube and face with each other directly opposite, the upper segment is converging cone shape, the lower segment is diverging cone shape, the ratio of the length of the upper segment bottom to the length of the lower segment bottom can be 0.1˜0.9, preferably 0.15˜0.25.

### CROSS-REFERENCE TO RELATED APPLICATIONS

This application claims priority to U.S. Provisional Patent Application Ser. No. 63/415,388 filed Oct. 12, 2022 titled GAS INLET TUBE ASSEMBLY FOR AN IMPROVED GAS MIXTURE IN A SUBSTRATE PROCESSING APPARATUS, the disclosure of which is hereby incorporated by reference in its entirety.

### FIELD OF INVENTION

The present disclosure relates to a substrate processing apparatus for processing a substrate, particularly to a gas inlet tube used in a substrate processing apparatus for improving gas mixture used for processing the substrate.

### BACKGROUND OF THE DISCLOSURE

In current reaction chamber configuration in FIG. 1, the gases which are used for substrate processing are supplied through gas inlet tube 7 above a showerhead 3.

The gas inlet tube 7 has two gas entry points at the top area, through which different process gases are fed, first inlet 5 and second inlet 6.

The process gases can enter through first inlet 5 or second inlet 6 or both. The exit/outlet of the inlet tube is showerhead 7 back volume. At the outlet/exit of the inlet tube, a homogeneous gas mixture is expected.

If the mixing is not uniform, this will impact the on-wafer film uniformity & property. The probability of process gases not mixing uniformly will increase if the first inlet 5 & the second inlet 6 have different mass flow rate of gases.

Due to the disadvantages, the present disclosure presents an improved gas inlet tube assembly for use in a reaction chamber for better gas mixture.

### SUMMARY OF THE DISCLOSURE

This summary is provided to introduce a selection of concepts in a simplified form. These concepts are described in further detail in the detailed description of example embodiments of the disclosure below.

This summary is not intended to identify key features or essential features of the claimed subject matter, nor is it intended to be used to limit the scope of the claimed subject matter.

In accordance with one embodiment there may be provided, a gas inlet tube assembly for use in a substrate processing apparatus, comprising a first inlet configured to insert a first process gas and a second inlet configured to insert a second process gas; and a gas inlet tube configured to mix the first process gas from the first inlet and the second process gas from the second inlet, the gas inlet tube being in fluid communication with a reaction chamber of the substrate processing apparatus, and comprising upper and lower segments; wherein the first inlet and the second inlet are placed in the upper segment of the gas inlet tube and face with each other directly opposite, and the upper segment of the gas inlet tube is converging cone shape, the lower segment of the gas inlet tube is diverging cone shape, and the ratio of the length of the upper segment (H1) to the length of the gas inlet tube (H) can be 0.1˜0.9, preferably 0.15˜0.25.

In at least one aspect, the gas inlet tube assembly's first inlet and second inlet have different diameters from each other.

In at least one aspect, the gas inlet tube assembly's first inlet and second inlet being diverging cone shape or converging cone shape in the connecting area to the gas inlet tube.

In at least one aspect, the ratio of the width of converging cone bottom (W1) to the width of the diverging cone bottom (W) can be 0.1˜0.9, preferably 0.4˜0.6.

In accordance with another embodiment, a substrate processing apparatus comprising a reaction chamber for processing a substrate, comprising a substrate support; a first inlet and a second inlet configured to insert a first process gas and a second process gas into the reaction chamber respectively; a gas inlet tube configured to mix the first process gas from the first inlet and the second process gas from the second inlet, the gas inlet tube being in fluid communication with the reaction chamber, and comprising upper and lower segments; and a showerhead assembly defining a reaction space together with a substrate support, the showerhead assembly comprising a plurality of holes connected to the gas inlet tube to supply the mixed process gas to the reaction space, wherein the first inlet and the second inlet are placed in the upper segment of the gas inlet tube and face with each other directly opposite, and the upper segment of the gas inlet tube is converging cone shape, the lower segment of the gas inlet tube is diverging cone shape, the ratio of the length of the upper segment (H1) to the length of the gas inlet tube (H) can be 0.1˜0.9, preferably 0.15˜0.25.

In at least one aspect, the substrate processing apparatus further comprising a gas exhaust hole for exhausting gas from the reaction chamber.

In at least one aspect, the substrate processing apparatus's first inlet and second inlet have different diameters from each other.

In at least one aspect, the substrate processing apparatus's first inlet and second inlet being diverging cone shape or converging cone shape in the connection area to the gas inlet tube.

In at least one aspect, the gas inlet tube assembly's ratio of the width of converging cone bottom (W1) to the width of the diverging cone bottom (W) can be 0.1˜0.9, preferably 0.4˜0.6.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a prior art showing reaction chamber's gas inlet tube.

FIG. 2 illustrates a view of the gas inlet tube assembly and the reaction chamber according to an embodiment of the present disclosure.

FIG. 3 illustrates variations of shapes of first and second inlets according to another embodiment of the present disclosure.

FIG. 4 illustrates top view of the gas inlet tube according to an embodiment of the present disclosure.

FIG. 5 illustrates a comparison of the gas mixture efficiency between the prior art shown in FIG. 1 and the present disclosure shown in FIG. 2.

FIG. 6 illustrates the H1/H ratio (a ratio of the length of upper segment to the length of the gas inlet tube) changes according to another embodiment of the present disclosure.

FIG. 7 illustrates the W1/W ratio (a ratio of the width of the converging cone bottom to the width of the diverging cone bottom) changes according to another embodiment of the present disclosure.

FIG. 8 illustrates a comparison of the gas mixture efficiency between a gas inlet tube with H1/H ratio of 0.25 and one with H1/H ratio of 0.75.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

The present disclosure will be explained with the figures.

Multiple gases may be used in semiconductor process. And the quality of substrate after processes may be mainly measured in the uniformity of the on-wafer film, thickness, etc.

For this reason, it is essential for the gases in the chamber for processing the substrate to be mixed well enough.

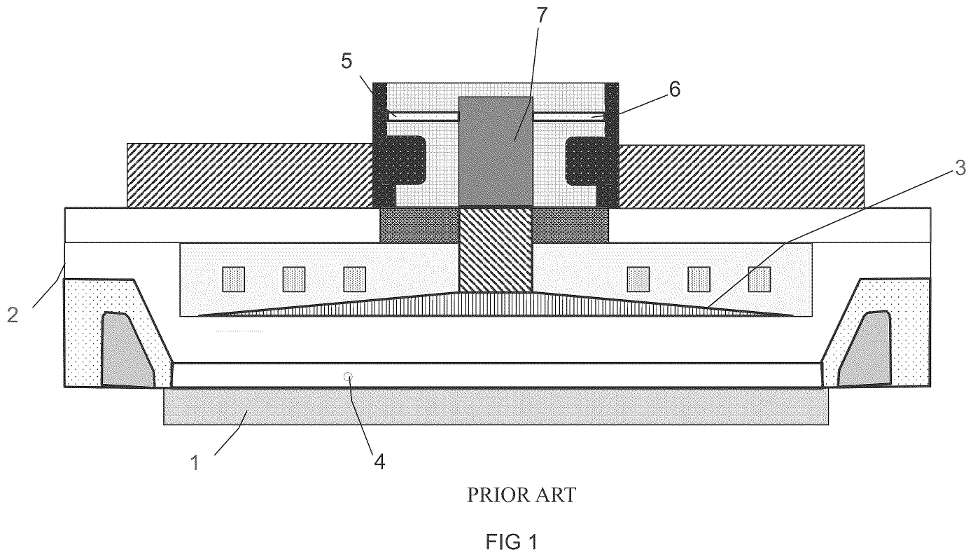

Conventional layout of the chamber with gas inlets is illustrated in FIG. 1.

In FIG. 1, there are two inlets 5, 6 which are used to insert different gases into the gas inlet tube 7. Customarily, it is believed that the speed of the gases from the two inlets 5, 6 forces the gases to mix with a vortex in the gas inlet tube 7.

However, when the inlets 5, 6 have different mass flow of process gases, the expected mixture of gases doesn't seem to be reached.

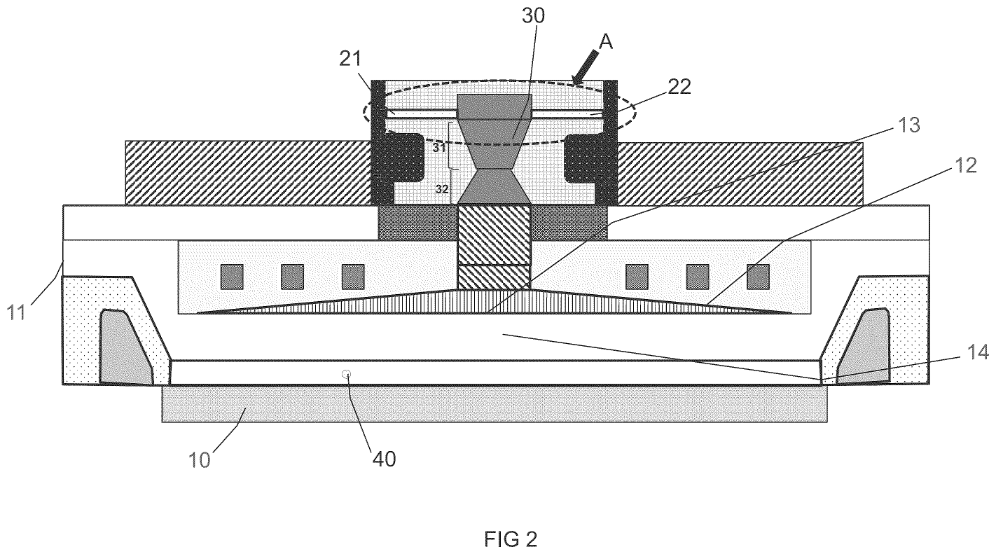

To solve this ill-mixed gas problem, an embodiment according to the present disclosure is shown in FIG. 2. The gas inlet tube 30 may not be cylindrical shape. On the contrary, the gas inlet tube 30 has 2 distinctively shaped parts and these will be explained later.

A first gas may come from the first inlet 21 and a second gas may come from the second inlet 22. The gases may be mixed and move downward until it would be sprayed through the many holes 13 in the showerhead assembly 12. The pressure in the reaction chamber 11 and the reaction space 14 when in processing may be usually 3˜10 T (torr) which can be changed in view of the process circumstances.

The reaction chamber 11 also comprises substrate support 10 and gas exhaust hole 40. The showerhead assembly 12, along with the substrate support 10 forms a reaction space 14 where the process gas (mixed in the gas inlet tube 30) may be supplied for substrate processing through the holes 13 in the showerhead assembly 12. Although the holes may not be directly visible in the drawings, there are many holes 13 in the showerhead assembly 12.

FIG. 2's A illustrates that first and second inlets 21, 22 and the gas inlet tube 30 may form a manifold. However, the gas inlet tube 30 has 2 segments whose shapes may be quite different from each other.

The upper segment 31 of the gas inlet tube 30 may be shaped a downwardly converging cone and the lower segment 32 may be shaped a downwardly diverging cone.

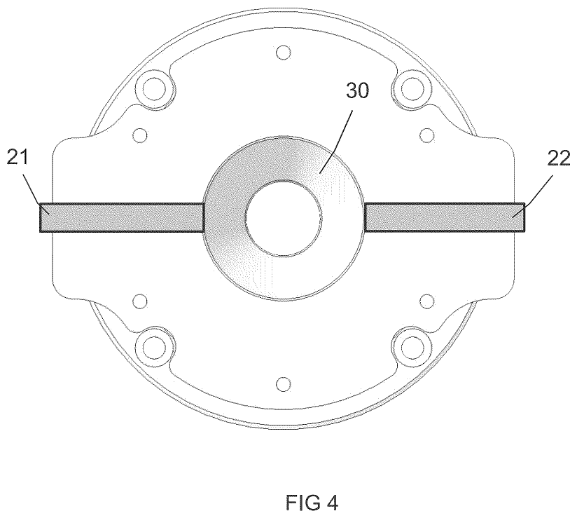

The two inlets 21, 22 may face with each other directly opposite side across the gas inlet tube 30 is illustrated in FIG. 4.

The 2 segments of gas inlet tube 30 can generate increased turbulence and vortex within the cavity and eventually can lead to an improved gas mixing.

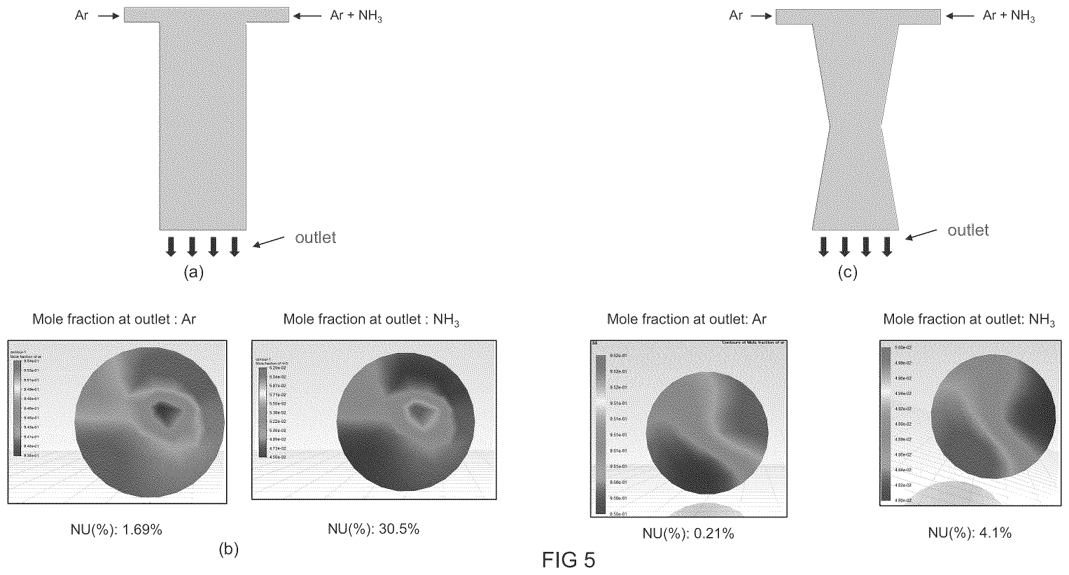

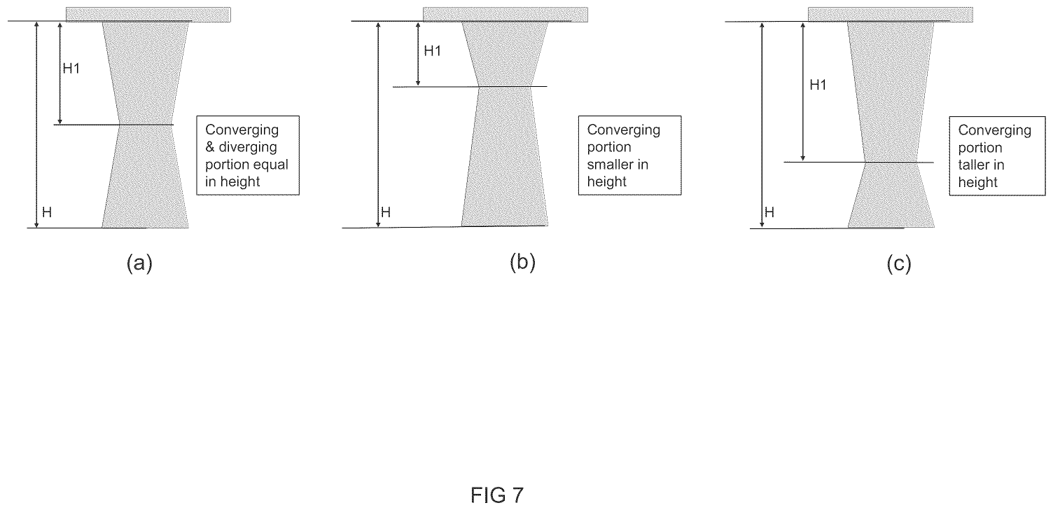

The efficiency of the present disclosure would be explained with test results from FIGS. 5 and 7.

In FIG. 5, the two gas inlet tube assemblies, i.e. (a) conventional shape and (c) present disclosure's embodiment shape, are given with the same condition for tests. For each case, the gas flow rate of inlet 1 (Ar) may be about 3 to 4 times that of inlet 2 (Ar+NH3). The outlets are located at the bottom of each of the gas inlet tubes.

(b) and (d) show the non-uniformity rate for each gas in the test in mole fraction respectively.

The Argon gas non-uniformity rate in the conventional shape (a) is measured to be 1.69% (b) while that of the present disclosure's shape (c) is measured to be 0.21% (d). Also, the NH3 gas non-uniformity rate in the conventional shape (a) is measure to be 30.5% while that of the present disclosure's shape (c) is measure to be 4.1% (d).

From FIG. 5's results, the non-uniformity rate is quite decreased from 1.69% to 0.21% (Ar), from 30.5% to 4.1% (Ar+NH3), which may show that the gases are better mixed within the present disclosure's shape.

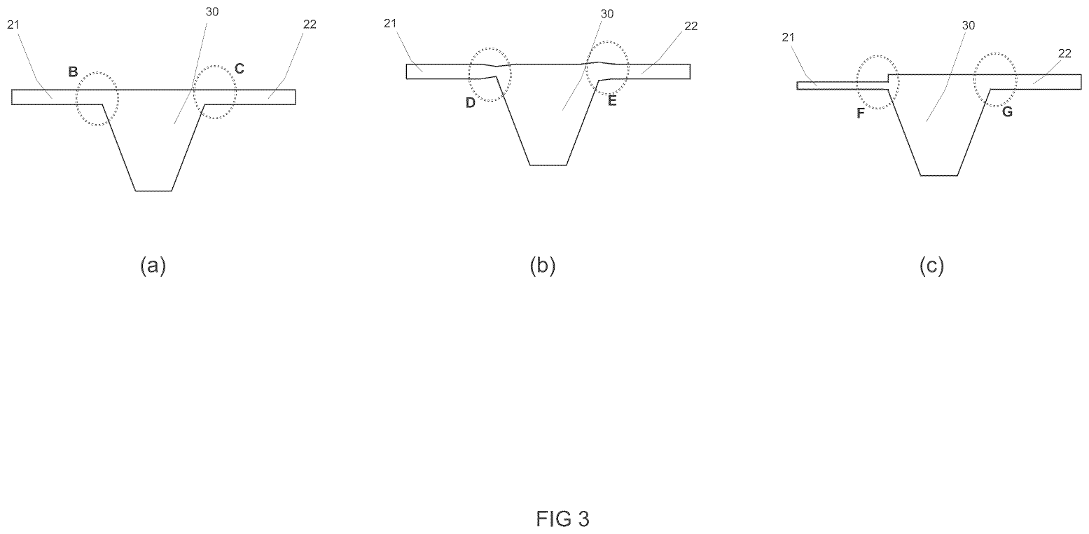

To be more efficient in mixing the gases with the induced turbulence and vortex in the gas inlet tube 30, the shape of the first inlet 21 and second inlet 22 are presented in FIG. 3.

FIG. 3 (a) illustrates the passages into the gas inlet tube 30 of the first inlet 21 (B) and the second inlet 22 (C). In FIG. 3's (b) and (c), different shapes of the passages of the first and second inlets 21, 22 into the gas inlet tube 30 may be illustrated.

In FIG. 3 (b), the shape of passage of the inlets 21, 22 into the gas inlet tube 30 may be diverging cone shape or converging cone shape toward the gas inlet tube 30. This drawing is just an example and the shape can be both diverging cones or converging cones.

The diameter or shape (converging/diverging) can be changed in view of the volume of the gas each inlet has for the processing for maximum mixture of the gas.

Apart from the inlet shapes, the ratio of the length of upper segment of the gas inlet tube (H1) to the length of the gas inlet tube (H), H1/H, can change.

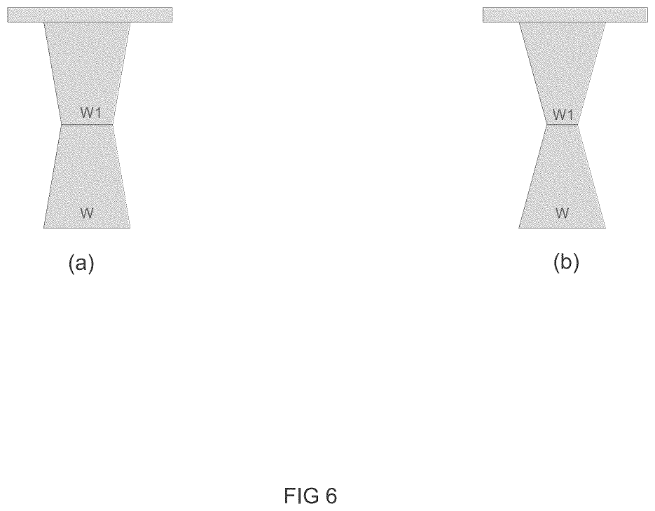

FIG. 6 illustrates some variances of the ratio (H1/H). In (a), the ratio is 0.5 but (b) has ratio less than 0.5 and (c) has ratio more than 0.5 respectively.

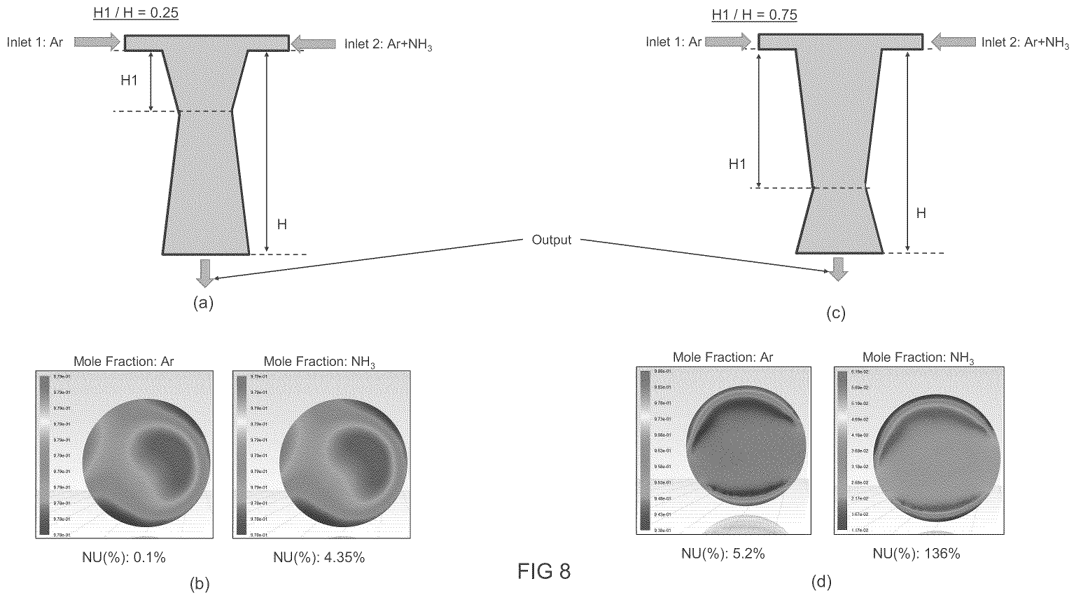

FIG. 8 illustrates the efficiency of gas mixture with respect to the ratio change.

FIGS. 8 (a) and (c) both have identical gas flow rate except the respective H1/H ratio. First inlet (inlet 1) has Ar gas input and the second inlet (inlet 2) has an input of Ar & NH3 gas mixture. The efficiency of gas mixture is measured at the output. The gas flow rate of inlet 1 (Ar) may be 9 to 10 times to that of inlet 2 (Ar+NH3).

(a)'s H1/H ratio is 0.25 and the non-uniformity rate for Ar and NH3 in this case are 0.1% and 4.35% respectively and (c)'s H1/H ratio is 0.75 and the non-uniformity rate for Ar and NH3 are 5.2% and 136% respectively.

In view of FIG. 8, it can be readily deduced that smaller H1/H ratio is better for gas mixture.

The H1/H ratio can vary from 0.1 to 0.9 but too small ratio would mean a rather short time in the converging cone area for mixing. Therefore, the range of 0.15 to 0.25 is preferable for H1/H ratio.

In FIG. 7, the different embodiments of the present disclosure are illustrated.

The width of the converging cone (upper segment) bottom is designated as W1 and the width of the diverging cone (lower segment) bottom is designated as W in FIG. 7.

The W1/W ratio can vary from 0.1 to 0.9 for maximizing the gas mixture efficiency just like the H1/H ratio does. However, W1/W ratio is usually set to 0.4˜0.6, i.e., about 0.5.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A gas inlet tube assembly used in a substrate processing apparatus, comprising:
a first inlet configured to insert a first process gas and a second inlet configured to insert a second process gas; and
a gas inlet tube configured to mix the first process gas from the first inlet and the second process gas from the second inlet, the gas inlet tube being in fluid communication with a reaction chamber of the substrate processing apparatus, and comprising upper and lower segments;
wherein the first inlet and the second inlet are placed in the upper segment of the gas inlet tube and face with each other directly opposite, and
the upper segment of the gas inlet tube is converging cone shape,
the lower segment of the gas inlet tube is diverging cone shape, and
the ratio of the length of the upper segment (H1) to the length of the gas inlet tube (H) can be 0.1˜0.9, preferably 0.15˜0.25.

2. The gas inlet tube assembly according to the claim 1, wherein
the first inlet and the second inlet have different diameters from each other.

3. The gas inlet tube assembly according to the claim 1, wherein
the first inlet and the second inlet being diverging cone shape or converging cone shape in the connecting area to the gas inlet tube.

4. The gas inlet tube assembly according to the claim 1, wherein
the ratio of the width of upper segment bottom (W1) to the width of the lower segment bottom (W) can be 0.1˜0.9, preferably about 0.4˜0.6.

5. A substrate processing apparatus comprising:
a reaction chamber for processing a substrate, comprising a substrate support;
a first inlet and a second inlet configured to insert a first process gas and a second process gas into the reaction chamber respectively;
a gas inlet tube configured to mix the first process gas from the first inlet and the second process gas from the second inlet, the gas inlet tube being in fluid communication with the reaction chamber, and comprising upper and lower segments; and
a showerhead assembly defining a reaction space together with a substrate support, the showerhead assembly comprising a plurality of holes connected to the gas inlet tube to supply the mixed process gas to the reaction space,
wherein the first inlet and the second inlet are placed in the upper segment of the gas inlet tube and face with each other directly opposite, and
the upper segment of the gas inlet tube is converging cone shape,
the lower segment of the gas inlet tube is diverging cone shape,
the ratio of the length of the upper segment (H1) to the length of the gas inlet tube (H) can be 0.1˜0.9, preferably 0.15˜0.25.

6. The substrate processing apparatus according to claim 5, further comprising: a gas exhaust hole for exhausting gas from the reaction chamber.

7. The substrate processing apparatus according to claim 5, wherein:
the first inlet and the second inlet have different diameters from each other.

8. The substrate processing apparatus according to claim 5, wherein
the first inlet and the second inlet being diverging cone shape or converging cone shape in the connection area to the gas inlet tube.

9. The substrate processing apparatus according to claim 5, wherein
the ratio of the width of upper segment bottom (W1) to the width of the lower segment bottom (W) can be 0.1˜0.9, preferably about 0.4˜0.6.
